(19) United States
(12) Patent Application Publication
(10) Pub. No.: US 2026/0293132 A1
(43) Pub. Date: Sep. 24, 2026

(54) MANUFACTURING METHOD OF SEMICONDUCTOR DEVICE AND SEMICONDUCTOR DEVICE

(71) Applicant: Kioxia Corporation, Tokyo (JP)

(72) Inventors: Kosuke HORIBE, Yokkaichi Mie (JP); Hiroshi NOGUCHI, Yokkaichi Mie (JP); Shinji NAKADA, Yokkaichi Mie (JP); Shota KASHIYAMA, Mie Mie (JP)

(21) Appl. No.: 19/317,896

(22) Filed: Sep. 3, 2025

(30) Foreign Application Priority Data
Mar. 18, 2025 (JP) 2025-043908

(51) Int. Cl. H10B 43/27

(52) U.S. Cl. CPC H10B 43/27

(57) ABSTRACT

A manufacturing method of a semiconductor device is provided. The manufacturing method includes forming a first stack of films, forming a first hole penetrating the first stack of films in a first direction, forming a metal film in the first hole near an upper end of the first hole, forming a carbon film on an upper surface of the metal film in the first hole to reach an upper end of the first hole, forming a second stack of films on the first stack of films, forming above the first hole a second hole penetrating the second stack of films in the first direction to reach the carbon film or the metal film, and removing the carbon film and the metal film to communicate the first hole with the second hole.

### CROSS-REFERENCE TO RELATED APPLICATION

This application is based upon and claims the benefit of priority from Japanese Patent Application No. 2025-043908, filed Mar. 18, 2025, the entire contents of which are incorporated herein by reference.

### FIELD

Embodiments described herein relate generally to a manufacturing method of a semiconductor device and a semiconductor device.

### BACKGROUND

When forming a deep hole in a stacked film in which insulating films and sacrifice films are alternately stacked, an upper hole is formed on a lower hole by using an etching stop layer, and then the etching stop layer is removed to communicate the upper hole with the lower hole.

### BRIEF DESCRIPTION OF THE DRAWINGS

FIG. 1 is a cross-sectional diagram showing an example of the configuration of a semiconductor device according to a first embodiment.

FIG. 2 is a vertical cross-sectional diagram showing a columnar portion of the semiconductor device according to the first embodiment.

FIG. 3 is a horizontal cross-sectional diagram showing the columnar portion of the semiconductor device according to the first embodiment.

FIG. 4 is a cross-sectional diagram showing a process step of a manufacturing method of the semiconductor device according to the first embodiment.

FIGS. 5A and 5B are cross-sectional diagrams showing other process steps of the manufacturing method of the semiconductor device according to the first embodiment.

FIGS. 6A and 6B are cross-sectional diagrams showing other process steps of the manufacturing method of the semiconductor device according to the first embodiment, subsequent to the process steps shown in FIGS. 5A and 5B.

FIGS. 7A and 7B are cross-sectional diagrams showing other process steps of the manufacturing method of the semiconductor device according to the first embodiment, subsequent to the process steps shown in FIGS. 6A and 6B.

FIGS. 8A and 8B are cross-sectional diagrams showing other process steps of the manufacturing method of the semiconductor device according to the first embodiment, subsequent to the process steps shown in FIGS. 7A and 7B.

FIGS. 9A and 9B are cross-sectional diagrams showing other process steps of the manufacturing method of the semiconductor device according to the first embodiment, subsequent to the process steps shown in FIGS. 8A and 8B.

FIGS. 10A and 10B are cross-sectional diagrams showing other process steps of the manufacturing method of the semiconductor device according to the first embodiment, subsequent to the process steps shown in FIGS. 9A and 9B.

FIGS. 11A and 11B are cross-sectional diagrams showing a manufacturing method of a semiconductor device according to a comparative example.

FIG. 12 is a cross-sectional diagram showing a process step of a manufacturing method of a semiconductor device according to a second embodiment.

FIG. 13 is a cross-sectional diagram showing a process step of a manufacturing method of a semiconductor device according to a third embodiment.

FIGS. 14A and 14B are cross-sectional diagrams showing a process step of a manufacturing method of a semiconductor device according to a fourth embodiment.

### DETAILED DESCRIPTION

Embodiments provide a manufacturing method of a semiconductor device and a semiconductor device capable of achieving both an increase in the width of the bottom of a hole on an etching stop layer and an etching selectivity using the etching stop layer.

In general, according to an embodiment, a manufacturing method of a semiconductor device includes forming a first stack of films including a plurality of first insulating films and a plurality of first sacrifice films alternately stacked in a first direction. The method further includes forming at least one first hole penetrating the first stack of films in the first direction. The method further includes forming a metal film in the first hole near an upper end of the first hole. The method further includes forming a carbon film on an upper surface of the metal film in the first hole to reach the upper end of the first hole. The method further includes forming a second stack of films having a plurality of second insulating films and a plurality of second sacrifice films alternately stacked in the first direction on the first stacked film. The method further includes forming above the first hole at least one second hole penetrating the second stack of films in the first direction to reach the carbon film or the metal film. The method further includes removing the carbon film and the metal film to communicate the first hole with the second hole.

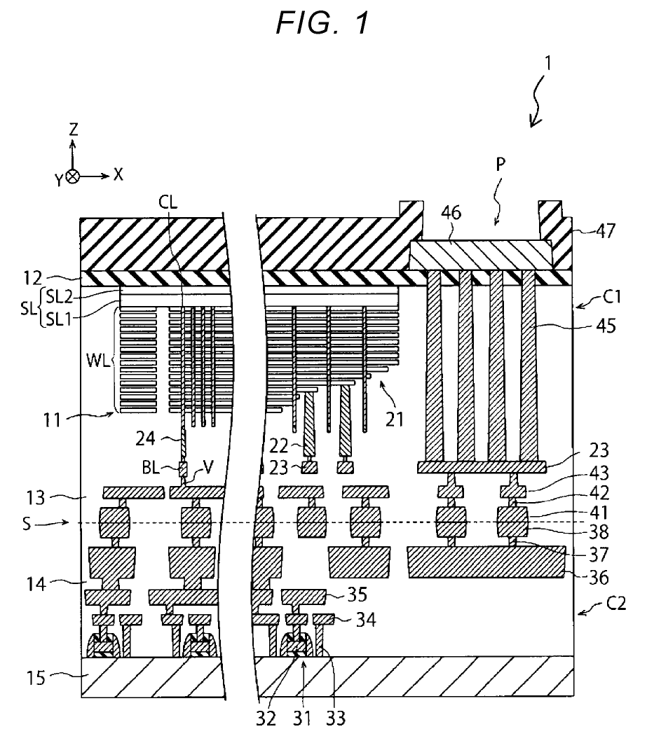

Hereinafter, embodiments of the disclosure will be described with reference to the drawings. In FIGS. 1 to 14, the same or similar components are given the same reference symbols, and duplicated descriptions are omitted.

### First Embodiment

FIG. 1 is a cross-sectional diagram showing an example of a configuration of a semiconductor device according to a first embodiment. The semiconductor device 1 shown in FIG. 1 is a three-dimensional memory in which an array chip C1 and a circuit chip C2 are bonded together. The semiconductor device 1 has a CMOS directly bonded to array (CBA) structure.

The array chip C1 includes a memory cell array 11 including a plurality of memory cells arranged three-dimensionally, an insulating film 12 on the memory cell array 11, and an interlayer insulating film 13 below the memory cell array 11. The insulating film 12 is, for example, a silicon oxide film or a silicon nitride film. The interlayer insulating film 13 is, for example, a silicon oxide film or a stacked film including a silicon oxide film and other insulating films.

The circuit chip C2 is provided under the array chip C1. The circuit chip C2 functions as a control circuit (logic circuit) that controls the operation of the array chip C1. The circuit chip C2 includes an interlayer insulating film 14 and a substrate 15 below the interlayer insulating film 14. The interlayer insulating film 14 is, for example, a silicon oxide film or a stacked film including a silicon oxide film and other insulating films. The substrate 15 is, for example, a semiconductor substrate such as a silicon substrate. FIG. 1 shows the X and Y directions parallel to the front surface, that is, the upper surface, of the substrate 15 and perpendicular to each other, and the Z direction perpendicular to the upper surface of the substrate 15. The Z and -Z directions are examples of a first direction. The X and -X directions, and the Y and -Y directions are examples of a second direction intersecting the first direction. Hereinafter, when the Z direction is facing upward in the drawings to which reference is made, the Z direction may be referred to as the upward direction, and the -Z direction may be referred to as the downward direction. On the other hand, when the Z direction is facing downward in the drawings to which reference is made, the -Z direction may be referred to as the upward direction, and the Z direction may be referred to as the downward direction.

The array chip C1 includes, as components of the memory cell array 11, a plurality of word lines WL, a plurality of columnar portions CL, a source line SL, and a select gate line (not shown). A staircase portion 21 is provided at the end of the memory cell array 11 in the X direction. Each word line WL is electrically connected to a wiring layer 23 via a contact plug 22. The plurality of columnar portions CL penetrate the plurality of word lines WL in the Z direction. Each columnar portion CL is electrically connected to a bit line BL in the same layer as the wiring layer 23 via a via plug 24. In addition, each columnar portion CL is electrically connected to a source line SL. The source line SL includes a first layer SL1 which is a semiconductor layer and a second layer SL2 which is a metal layer. A wiring layer 43 including a via plug V is provided below the bit line BL. A via plug 42 is provided below the wiring layer 43. A plurality of metal pads 41 are provided below the via plug 42. The metal pad 41 is, for example, a copper (Cu) layer or an aluminum (Al) layer.

The array chip C1 further includes a plurality of via plugs 45 provided on the wiring layer 23, a metal pad 46 provided on the via plugs 45 and on the insulating film 12, and a passivation film 47 provided on the metal pad 46 and on the insulating film 12. The metal pad 46 is, for example, a Cu layer or an Al layer, and functions as an external connection pad (bonding pad) of the semiconductor device in FIG. 1. The passivation film 47 is, for example, an insulating film such as a silicon oxide film. The passivation film 47 has an opening P through which the upper surface of the metal pad 46 is exposed. The metal pad 46 can be connected via the opening P to a mounting board or other devices by bonding wires, solder balls, metal bumps, or the like.

The circuit chip C2 includes a plurality of transistors 31. Each transistor 31 includes a gate electrode 32 provided on the substrate 15 via a gate insulating film, and a source diffusion layer and a drain diffusion layer (not shown) provided in the substrate 15. Further, the circuit chip C2 includes a plurality of contact plugs 33 provided on the source diffusion layer or drain diffusion layer of the transistor 31, a wiring layer 34 provided on the contact plugs 33 and including a plurality of wirings, and a wiring layer 35 provided on the wiring layer 34 and including a plurality of wirings.

The circuit chip C2 further includes a wiring layer 36 provided on the wiring layer 35 and including a plurality of wirings, a plurality of via plugs 37 provided on the wiring layer 36, and a plurality of metal pads 38 provided on the via plugs 37. The metal pads 38 are provided below the metal pads 41 of the array chip C1.

The circuit chip C2 is attached to the array chip C1 at an attachment surface S. Specifically, the interlayer insulating film 13 of the array chip C1 and the interlayer insulating film 14 of the circuit chip C2 are attached to each other at the attachment surface S. Further, the metal pads 41 of the array chip C1 and the metal pads 38 of the circuit chip C2 are attached to each other at the attachment surface S. Thus, the array chip C1 and the circuit chip C2 are electrically connected via the metal pads 38, 41.

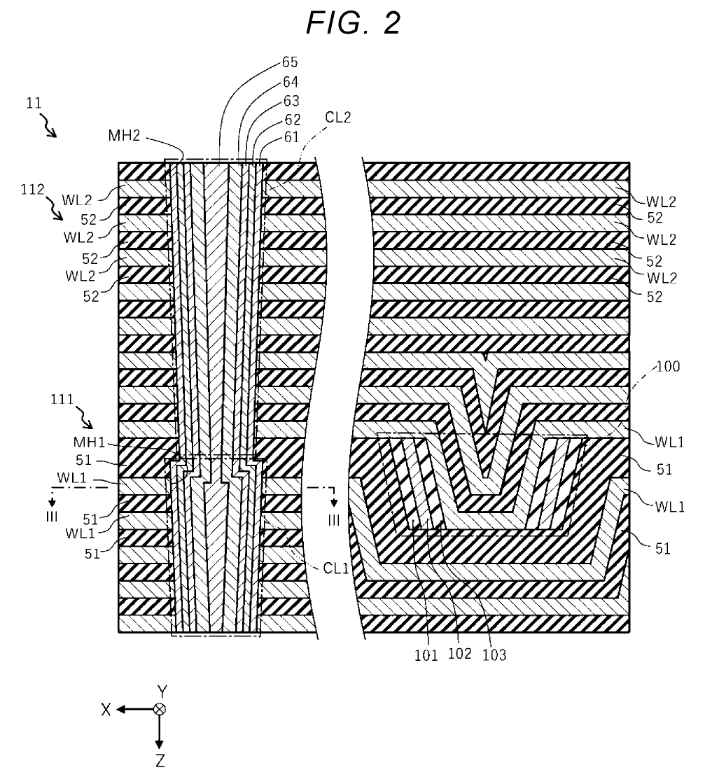

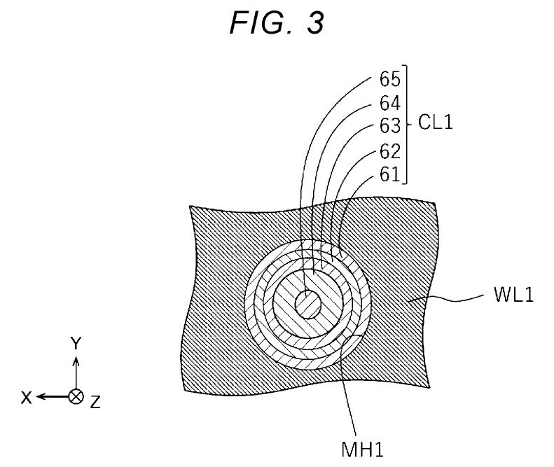

FIG. 2 is a cross-sectional diagram showing the structure of the columnar portion CL in the semiconductor device 1 according to the first embodiment. FIG. 3 is a cross-sectional diagram showing a cross section taken along line III-III of FIG. 2, including the structure of the columnar portion CL in the semiconductor device 1 according to the first embodiment. Furthermore, in FIG. 2, the array chip C1 is upside down compared to FIG. 1.

As shown in FIG. 2, the memory cell array 11 includes lower stacked films 111 and an upper stacked film 112 on the interlayer insulating film 13 shown in FIG. 1. The lower stacked films 111 are an example of a first stack of films. The upper stacked films 112 are an example of a second stack of films.

The lower stacked films 111 include a plurality of first word lines WL1 and a plurality of first insulating films 51 alternately stacked in the −Z direction. The first word lines WL1 configure a part of the word line WL shown in FIG. 1. The first word lines WL1 contain, for example, tungsten (W) as a main component. The first word lines WL1 may contain transition elements other than tungsten, such as molybdenum (Mo), titanium (Ti), and niobium (Nb). The first insulating film 51 is mainly configured with silicon oxide (SiO₂). The uppermost first insulating film 51 may be thicker than the lower first insulating film 51.

The upper stacked film 112 is continuously provided on the lower stacked films 111 in FIG. 2. The upper stacked film 112 includes a plurality of second word lines WL2 and a plurality of second insulating films 52 alternately stacked in the -Z direction. The second word lines WL2 form a part of the word line WL shown in FIG. 1. The second word lines WL2 contain, for example, tungsten as a main component. The second word lines WL2 may contain transition elements other than tungsten, such as molybdenum, titanium, and niobium. The second insulating films 52 are mainly configured with silicon oxide.

As shown in FIG. 2, the columnar portion CL shown in FIG. 1 includes a lower columnar portion CL1 and an upper columnar portion CL2. The lower columnar portion CL1 is an example of a first columnar portion. The upper columnar portion CL2 is an example of a second columnar portion.

The lower columnar portion CL1 is provided in the lower stacked films 111 so as to penetrate the lower stacked films 111 in the Z direction. That is, the lower columnar portion CL1 is provided in a first memory hole MH1 that penetrates the lower stacked films 111 in the Z direction. The first memory hole MH1 is an example of a first hole. In the example shown in FIG. 3, the horizontal cross-section of the first columnar portion CL1 has a circular shape. The first columnar portion CL1 includes, in order, a block insulating film 61, a charge storage film 62, a tunnel insulating film 63, a channel semiconductor film 64, and a core insulating film 65. The charge storage film 62 is, for example, a silicon nitride film. The charge storage film 62 is formed on the side surfaces of the first word line WL1 and the first insulating film 51 via the block insulating film 61. The charge storage film 62 may be a semiconductor layer such as a polysilicon layer. The channel semiconductor film 64 is, for example, a polysilicon layer. The channel semiconductor film 64 is formed on the side surface of the charge storage film 62 via the tunnel insulating film 63. The block insulating film 61, the tunnel insulating film 63 and the core insulating film 65 are, for example, silicon oxide films or metal insulating films.

The upper columnar portion CL2 is continuously provided on the lower columnar portion CL1. That is, the upper columnar portion CL2 is integral with the lower columnar portion CL1. The diameter of the bottom of the upper columnar portion CL2 is smaller than the diameter of the upper end of the lower columnar portion CL1. However, due to the manufacturing method according to the first embodiment described below, the bottom of the upper columnar portion CL2 has a sufficiently large diameter. Since the bottom of the upper columnar portion CL2 has a sufficiently large diameter, for example, it is possible to prevent an increase in electrical resistance and obtain good electrical characteristics.

The upper columnar portion CL2 is provided in the upper stacked films 112 to penetrate the upper stacked films 112 in the Z direction. That is, the upper columnar portion CL2 is provided in the second memory hole MH2 that penetrates the upper stacked films 112 in the Z direction. The second memory hole MH2 is an example of a second hole. Similar to the lower columnar portion CL1, the upper columnar portion CL2 includes, in order, a block insulating film 61, a charge storage film 62, a tunnel insulating film 63, a channel semiconductor film 64, and a core insulating film 65.

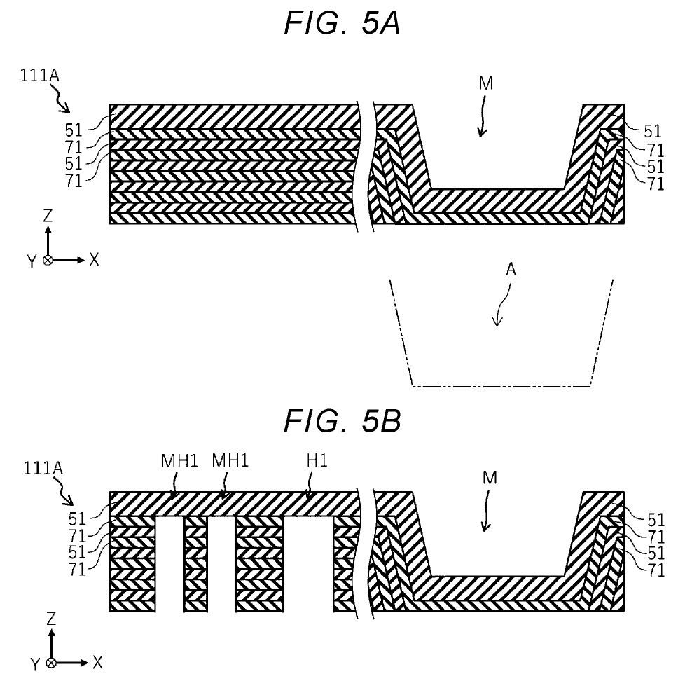

As shown in FIG. 2, a lower carbon film 101 is provided at a position away from the lower columnar portion CL1 in the -X direction, penetrating a region 100 on the upper end side of the lower stacked films 111, where a concave portion is formed in the lower stacked films 111 and a convex portion is formed in the upper stacked films 112. The lower carbon film 101 is an example of a second carbon film. The lower carbon film 101 is provided to extend in the Y direction. Further, the lower carbon films 101 are provided in a pair with a gap in the X direction. The lower carbon films 101 are provided at positions corresponding to the side walls of a concave mark portion M (see FIGS. 5A and 5B) used for aligning a mask for photolithography. The mark portion M will be described in detail below. The lower carbon film 101 is a film used as an etching stop layer for forming the second memory hole MH2.

When the direction from the pair of lower carbon films 101 toward the region sandwiched between the pair of lower carbon films 101 is defined as "inner side", a pair of metal films 102 respectively adjacent to the pair of lower carbon films 101 are provided on the inner side of the pair of lower carbon films 101. The pair of metal films 102 are provided to penetrate the region 100 on the upper end side of the lower stacked films 111 at a position away from the lower columnar portion CL1 in the -X direction and adjacent to the lower carbon film 101. The metal film 102 contains at least one of tungsten, titanium nitride (TiN), and molybdenum, for example. The metal film 102 may be a metal compound such as tungsten carbide (WC), tungsten boron carbide (WBC), and tungsten boride (WB). The metal film 102 is a film used as an etching stop layer for forming the second memory hole MH2 together with the lower carbon film 101.

When the direction from the pair of metal films 102 toward the region sandwiched between the pair of metal films 102 is defined as the "inner side", a pair of upper carbon films 103 respectively adjacent to the pair of metal films 102 are provided inner side the pair of metal films 102. The pair of upper carbon films 103 are provided at positions adjacent to the metal films 102 to penetrate the region 100 on the upper end side of the lower stacked films 111. The upper carbon film 103 is a film used as an etching stop layer for forming the second memory hole MH2 together with the lower carbon film 101 and metal film 102.

The shapes of the lower carbon film 101, the metal film 102, and the upper carbon film 103 in the region 100 and the lower stacked films 111 follow the shape of an opening A (see FIGS. 5A and 5B) formed in a under layer (not shown) (that is, an insulating layer) below the lower stacked films 111. That is, by forming above the opening A, lower stacked films 111A (see FIGS. 5A and 5B) before replacement to be described below, the shape of the stacked films 101, 102, 103, and 111 in the region 100 is formed. Further, the shape of the lower stacked films 111 below the region 100 follows the shape of the opening A. Furthermore, the shape of the upper stacked films 112 above the region 100 can follow the shape of the opening A up to a position higher than is shown in the figure.

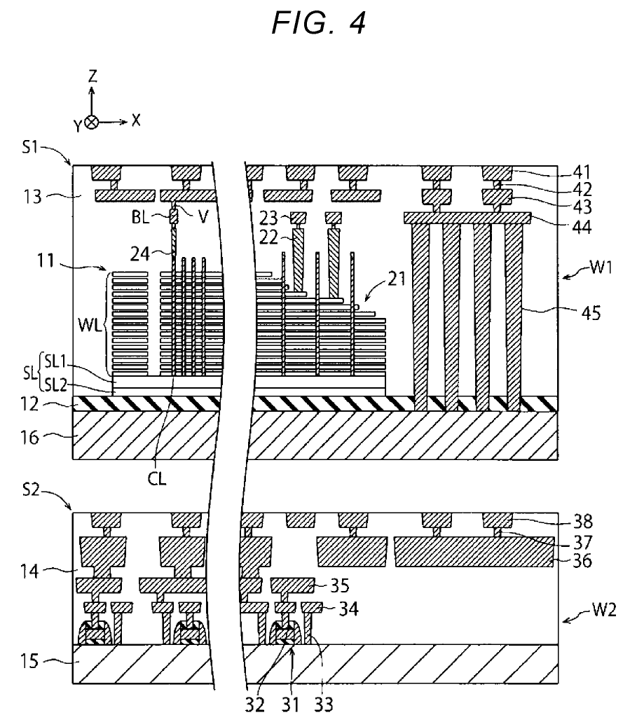

Next, a manufacturing method of the semiconductor device 1 having the above configuration will be described. FIG. 4 is a cross-sectional diagram showing a process step of a manufacturing method of the semiconductor device 1 according to the first embodiment. FIG. 4 shows a part of an array wafer W1 including a plurality of array chips C1 before dicing, and a part of a circuit wafer W2 including a plurality of circuit chips C2 before dicing. The array wafer W1 is also called a memory wafer, and the circuit wafer W2 is also called a CMOS wafer.

The orientation of the array wafer W1 in FIG. 4 is opposite to the orientation of the array chip C1 in FIG. 1. FIG. 4 shows the array wafer W1 before its orientation is reversed for bonding. The array wafer W1 and the circuit wafer W2 are bonded together and diced to manufacture the semiconductor device 1 in FIG. 1. That is, FIG. 1 shows the array chip C1 after its orientation is reversed for bonding, bonding, and dicing.

In FIG. 4, the symbol S1 indicates the upper surface of the array wafer W1. The symbol S2 indicates the upper surface of the circuit wafer W2. The array wafer W1 has a substrate 16 provided under the insulating film 12. The substrate 16 is, for example, a semiconductor substrate such as a silicon substrate.

In the first embodiment, first, as shown in FIG. 4, the memory cell array 11, insulating film 12, interlayer insulating film 13, staircase portion 21, metal pad 41, and the like are formed on the substrate 16 of the array wafer W1. Further, the interlayer insulating film 14, transistor 31, metal pad 38, and the like are formed on the substrate 15 of the circuit wafer W2. In this case, via plugs 45, a wiring layer 44, a wiring layer 43, via plugs 42, and metal pads 41 are formed in this order on the substrate 16. Further, contact plugs 33, a wiring layer 34, a wiring layer 35, a wiring layer 36, via plugs 37, and metal pads 38 are formed in this order on the substrate 15. Next, the orientation of the array wafer W1 is reversed such that the upper surface S1 of the array wafer W1 and the upper surface S2 of the circuit wafer W2 face each other. Next, the array wafer W1 and the circuit wafer W2 are bonded together by mechanical pressure. Thus, the interlayer insulating film 13 and the interlayer insulating film 14 are bonded together. Next, the array wafer W1 and the circuit wafer W2 are annealed, for example, at 400°C. Thus, the metal pad 41 and the metal pad 38 are bonded together.

After that, the substrate 15 is thinned by CMP, the substrate 16 is removed by CMP, and then the array wafer W1 and the circuit wafer W2 are cut into a plurality of chips. In this way, the semiconductor device 1 shown in FIG. 1 is manufactured. Furthermore, the metal pad 46 and passivation film 47 shown in FIG. 1 are formed on the insulating film 12, for example, after the substrate 15 is thinned and the substrate 16 is removed.

Although FIG. 1 shows the boundary surface between the interlayer insulating film 13 and the interlayer insulating film 14, and the boundary surface between the metal pad 41 and the metal pad 38, these boundary surfaces are generally not visible after the above-mentioned annealing. However, the positions of these boundary surfaces can be estimated by detecting, for example, the inclination of the side surface of the metal pad 41 or the side surface of the metal pad 38, or the positional deviation between the side surface of the metal pad 41 and the side surface of the metal pad 38.

FIGS. 5A and 5B are cross-sectional diagrams showing other process steps of the manufacturing method of the semiconductor device 1 according to the first embodiment. More specifically, first, an under layer (not shown) is formed above the substrate 16 (see FIG. 4). The under layer is, for example, an insulating layer. After forming the under layer, a concave opening A is formed by photolithography using a mask, on the upper surface of the under layer away in the X direction from the position where the first memory hole MH1 is formed (FIG. 5A). After forming the opening A, lower stacked films 111A is formed on the under layer by alternately stacking a plurality of first insulating films 51 and a plurality of first sacrifice films 71 in the Z direction (FIG. 5A). The lower stacked films 111A are an example of a first stack of films. The first sacrifice film 71 is a layer that is replaced with the first word line WL1. The first sacrifice film 71 is, for example, a silicon nitride film (SiN).

The concave mark portion M that follows the shape of the opening A is formed on the upper surface of the lower stacked films 111A formed on the opening A (FIG. 5A). The mark portion M is formed simultaneously with the formation of the lower stacked films 111A. The mark portion M is used to align a mask for photolithography for forming the first memory hole MH1 and the first hole H1 to be described below. The mark portion M is formed in the shape of a slit extending in the Y direction. As shown in FIGS. 5A and 5B, the shape of the lower stacked films 111A between the opening A and the mark portion M follows the shape of the opening A.

After forming the mark portion M, the first memory hole MH1 and the first hole H1 are formed to penetrate the lower stacked films 111A in the -Z direction (FIG. 5B). The first hole H1 has a larger diameter than the first memory hole MH1. The first hole H1 may be filled with an insulating layer for the purpose of reinforcing the stacked film when replacing the sacrifice film with an electrode layer, for example. Alternatively, the first hole H1 may be filled with a contact that electrically connects the upper layer wiring and the lower layer wiring. The first memory hole MH1 and the first hole H1 are formed by lithography using a mask aligned using the mark portion M and Reactive Ion Etching (RIE). By aligning the mask using the mark portion M, the first memory hole MH1 and the first hole H1 can be formed in the appropriate position.

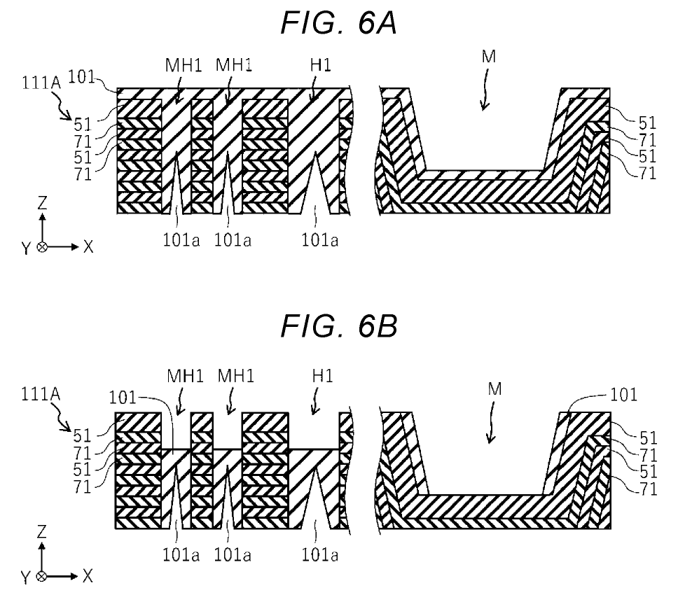

FIGS. 6A and 6B are cross-sectional diagrams showing other process steps of the manufacturing method of the semiconductor device 1 according to the first embodiment, subsequent to the process steps shown in FIGS. 5A and 5B. After forming the first memory hole MH1 and the first hole H1, the lower carbon film 101 is formed in the first memory hole MH1, in the first hole H1, and on the upper surface of the lower stacked films 111A (FIG. 6A). The lower carbon film 101 is also formed on the mark portion M. In this case, the lower carbon film 101 is formed such that a cavity 101a is formed by the first memory hole MH1 below the lower carbon film 101. Further, the lower carbon film 101 is formed such that the cavity 101a is formed by the first hole H1 below the lower carbon film 101. In other words, the lower carbon film 101 is formed so as not to completely fill the first memory hole MH1 and the first hole H1. The cavity 101a may be a cavity that is formed naturally (that is, unavoidably) in the process.

After forming the lower carbon film 101, the lower carbon film 101 is etched back (that is, processed) so that the upper surface of the lower carbon film 101 is recessed below the upper end of the first memory hole MH1 and the upper end of the first hole H1 (FIG. 6B). Thus, the lower carbon film 101 is formed such that its upper surface is located below the upper end of the first memory hole MH1 and below the upper end of the first hole H1. In this case, the lower carbon film 101 remains on both side walls in the X direction of the mark portion M.

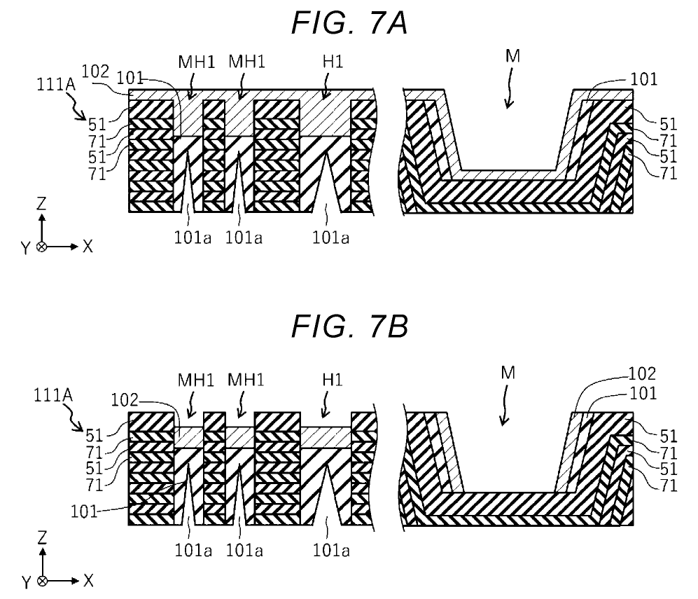

FIGS. 7A and 7B are cross-sectional diagrams showing other process steps of the manufacturing method of the semiconductor device 1 according to the first embodiment, subsequent to the process steps shown in FIGS. 6A and 6B. After etching back the lower carbon film 101, a metal film 102 is formed in the first memory hole MH1, in the first hole H1, and on the upper surface of the lower stacked films 111A (FIG. 7A). The metal film 102 is also formed on the mark portion M.

After forming the metal film 102, the metal film 102 is etched back so that the upper surface of the metal film 102 is recessed below the upper end of the first memory hole MH1 and the upper end of the first hole H1 (FIG. 7B). Thus, the metal film 102 is formed to be located below the upper end of the first memory hole MH1 from the upper surface of the lower carbon film 101 in the first memory hole MH1. Further, the metal film 102 is formed to be located below the upper end of the first hole H1 from the upper surface of the lower carbon film 101 in the first hole H1. In this case, the metal film 102 also remains on the lower carbon film 101 in the mark portion M.

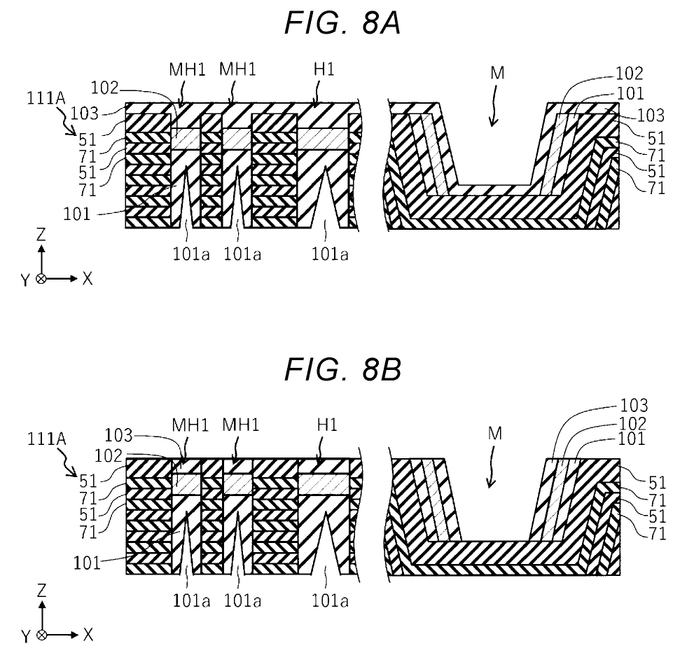

FIGS. 8A and 8B are cross-sectional diagrams showing other process steps of the manufacturing method of the semiconductor device 1 according to the first embodiment, subsequent to the process steps shown in FIGS. 7A and 7B. After etching back the metal film 102, the upper carbon film 103 is formed in the first memory hole MH1, in the first hole H1, and on the upper surface of the lower stacked films 111A (FIG. 8A). The upper carbon film 103 is also formed on the mark portion M.

After forming the upper carbon film 103, the upper carbon film 103 is etched back so that the upper surface of the upper carbon film 103 is retracted to the upper end of the first memory hole MH1 and the upper end of the first hole H1 (FIG. 8B). Thus, the upper carbon film 103 is formed to be located from the upper surface of the metal film 102 in the first memory hole MH1 to the upper end of the first memory hole MH1. Further, the upper carbon film 103 is formed to be located from the upper surface of the metal film 102 in the first hole H1 to the upper end of the first hole H1. In this case, the upper carbon film 103 remains on the metal film 102 in the mark portion M as well.

Through the steps shown in FIGS. 6 to 8, etching stop layers 101, 102, and 103 including an upper carbon film 103, a metal film 102, and a lower carbon film 101 are formed on the upper end side of the first memory hole MH1 and the upper end side of the first hole H1.

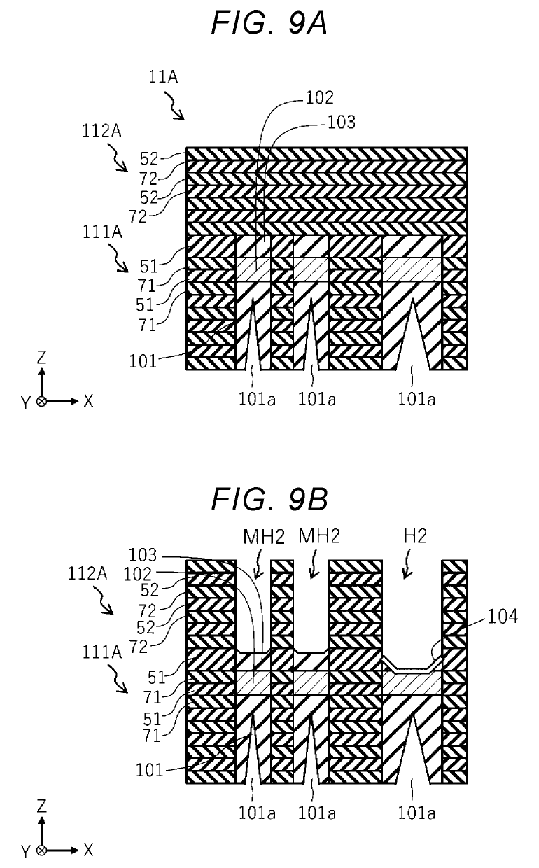

FIGS. 9A and 9B are cross-sectional diagrams showing other process steps of the manufacturing method of the semiconductor device 1 according to the first embodiment, subsequent to the process steps shown in FIGS. 8A and 8B. After etching back the upper carbon film 103, a plurality of second insulating films 52 and a plurality of second sacrifice films 72 are alternately stacked in the Z direction on the lower stacked films 111A and the upper carbon film 103 to form upper stacked films 112A (FIG. 9A). The upper stacked films 112A are an example of a second stack of films. The second sacrifice film 72 is a layer that is replaced with the second word line WL2. The second sacrifice film 72 is, for example, a silicon nitride film.

After forming the upper stacked films 112A, a second memory hole MH2 is formed above the first memory hole MH1, penetrating the upper stacked films 112A to reach the upper carbon film 103 or metal film 102 in the first memory hole MH1 (FIG. 9B). In the example shown in FIGS. 9A and 9B, the second memory hole MH2 is formed up to the upper carbon film 103 by partially removing the upper carbon film 103. The second memory hole MH2 is formed by lithography and RIE.

When forming the second memory hole MH2, a second hole H2 is formed above the first hole H1, penetrating the upper stacked films 112A to reach the upper carbon film 103 or metal film 102 in the first hole H1. In the example shown in FIGS. 9A and 9B, the second hole H2 is formed up to the metal film 102 by almost completely removing the upper carbon film 103. The second hole H2 is formed by lithography and RIE. A metal-based re-sputtered layer 104 is formed on the metal film 102 as a reaction product of the RIE.

When forming the second memory hole MH2 and the second hole H2, the etching stop layers 101, 102, 103 provided on the upper end side of the first memory hole MH1 and the upper end side of the first hole H1 include the metal film 102.

Since the metal film 102 with a high selectivity (that is, a low etching rate) is included, the etching stop layers 101, 102, and 103 can stop the etching for forming the second memory hole MH2 and the second hole H2 at an appropriate position (that is, height).

Furthermore, when forming the second memory hole MH2 and the second hole H2, the etching stop layers 101, 102, and 103 have the upper carbon film 103 in the uppermost layer. Since the etching stop layer 101, 102, and 103 has the upper carbon film 103 with a low selectivity (that is, a high etching rate) in the uppermost layer, it is possible to increase the diameter (that is, bottom CD or width) of the bottom of the second memory hole MH2 and the second hole H2. In other words, the tapering of the second memory hole MH2 and the second hole H2 can be prevented. By increasing the diameters of the bottoms of the second memory hole MH2 and the second hole H2, the diameters of the bottoms of the second columnar portion CL2 embedded in the second memory hole MH2 and the insulating layer embedded in the second hole H2 can be increased. This makes it possible to prevent an increase in the electrical resistance of the columnar portion CL and ensure good electrical characteristics of the memory cell array 11. In addition, the mechanical strength of the insulating layer in the second hole H2 can be ensured, and the collapse of the stacked film during replacement can be appropriately prevented.

Further, the etching stop layers 101, 102, and 103 have a lower carbon film 101 at the bottom layer. Due to the lower carbon film 101, the thickness of the metal film 102 can be reduced as much as possible. By reducing the thickness of the metal film 102, the etching stop layers 101, 102, and 103 can be appropriately removed.

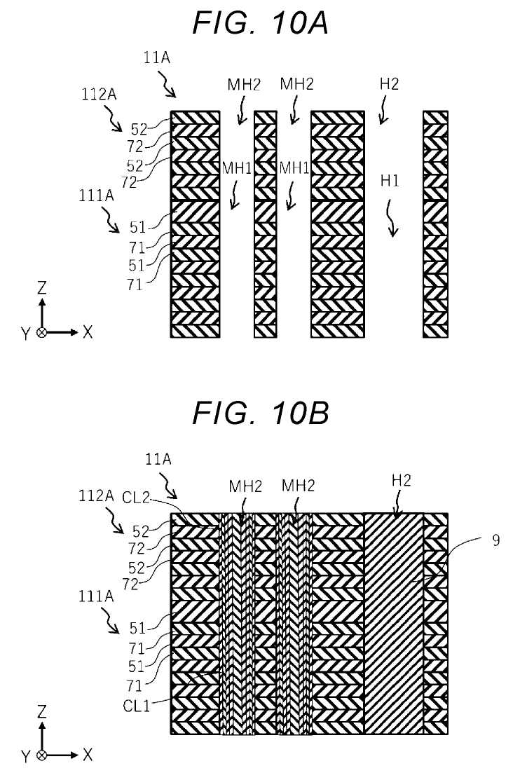

After forming the second memory hole MH2 and the second hole H2, the etching stop layers 101, 102, and 103 below the second memory hole MH2 are removed to communicate the first memory hole MH1 with the second memory hole MH2. Further, the etching stop layers 101, 102, and 103 below the second hole H2 are removed to communicate the first hole H1 with the second hole H2 (FIG. 10A).

The lower carbon film 101 and the upper carbon film 103 are removed, for example, by ashing. Further, the metal film 102 is removed, for example, by wet etching.

After removing the etching stop layers 101, 102, and 103, the first columnar portion CL1 and the second columnar portion CL2 are continuously formed in the first memory hole MH1 and the second memory hole MH2 (FIG. 10B). Further, the insulating layer 9 is continuously formed in the first hole H1 and the second hole H2. While the illustration of the insulating layer 9 is simplified in FIGS. 10A and 10B, the actual insulating layer 9 may be configured with a plurality of insulating films stacked in the radial direction of the holes H1 and H2, similar to the first columnar portion CL1 and the second columnar portion CL2.

After forming the first columnar portion CL1 and the second columnar portion CL2, the first sacrifice film 71 is replaced with the first word line WL1 and the second sacrifice film 72 is replaced with the second word line WL2 by wet etching. Then, the bonded wafer is diced into individual pieces to obtain the semiconductor device 1 of FIG. 1.

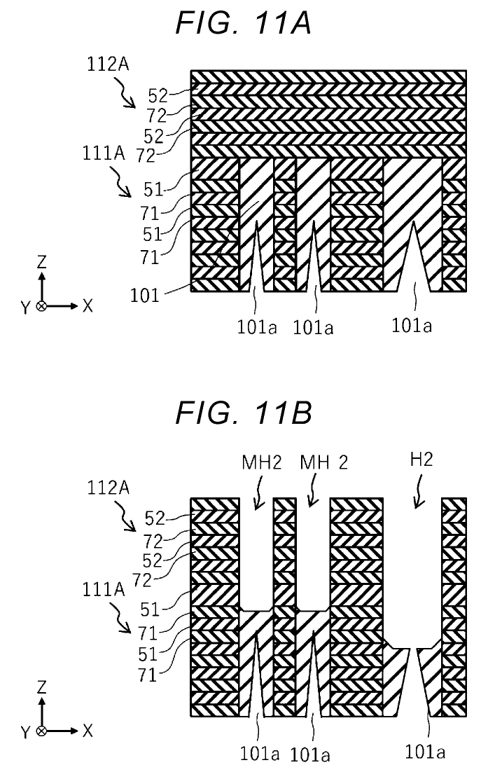

FIGS. 11A and 11B are cross-sectional diagrams showing process steps of a manufacturing method of a semiconductor device according to a comparative example. When the etching stop layer is formed only of the carbon film 101 (FIG. 11A), it becomes difficult to ensure the selectivity. For example, when forming the second hole H2 with a large diameter, there is a concern that the second hole H2 may penetrate the lower carbon film 101 and communicates with the cavity 101a (that is, the first hole H1) below the carbon film 101. In this case, there is a risk that the first hole H1 may be over-etched. In contrast, according to the first embodiment, the etching stop layer 101, 102, and 103 has the metal film 102, so that the selectivity can be ensured. In addition, the etching stop layer 101, 102, and 103 has the upper carbon film 103 in the uppermost layer, so that the diameters of the bottoms of the second memory hole MH2 and the second hole H2 can be increased. Therefore, according to the first embodiment, it is possible to achieve both an increase in the diameter of the bottom of the hole on the etching stop layer and a selectivity of etching using the etching stop layer.

### Second Embodiment

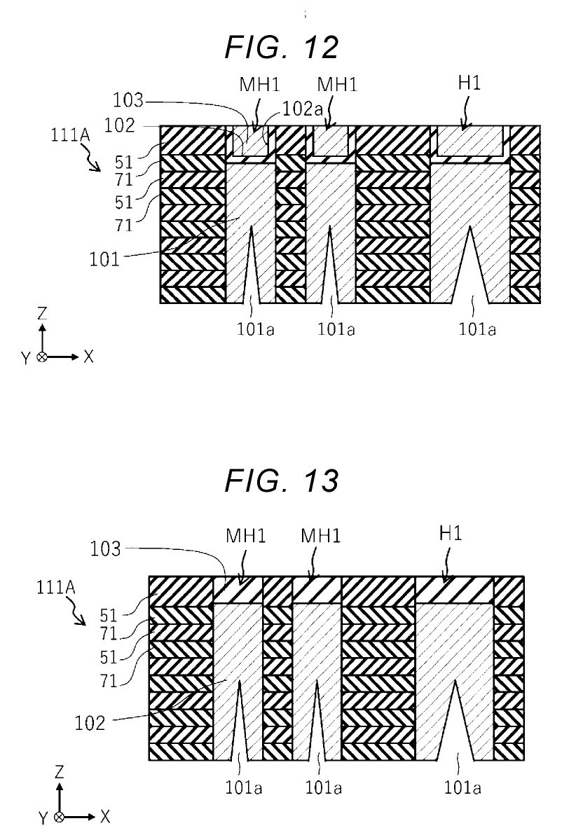

A second embodiment in which the metal film 102 is formed to have a recess portion will be described, focusing on the differences from the above-mentioned embodiment. FIG. 12 is a cross-sectional diagram showing a process step of a manufacturing method of a semiconductor device according to the second embodiment.

As shown in FIG. 12, in the second embodiment, when the metal film 102 is formed on the lower carbon film 101, the metal film 102 is formed to have a recess portion 102a. Further, in the second embodiment, when the upper carbon film 103 is formed on the metal film 102, the upper carbon film 103 is formed to fill the recess portion 102a.

According to the second embodiment, the amount of material used for the metal film 102 can be reduced, thereby reducing costs. Further, the time required for removing (that is, wet etching) the metal film 102 can be shortened.

### Third Embodiment

A third embodiment in which the formation of the lower carbon film 101 is omitted will be described, focusing on the differences from the above-mentioned embodiments. FIG. 13 is a cross-sectional diagram showing a process step of a manufacturing method of a semiconductor device according to the third embodiment.

Up to this point, an example has been described in which the lower carbon film 101 is formed below the metal film 102 before the metal film 102 is formed. In contrast, in the third embodiment, the metal film 102 and the upper carbon film 103 are formed as an etching stop layer on the upper end side of the first memory hole MH1 and the upper end side of the first hole H1.

According to the third embodiment, the etching selectivity when forming the second memory hole MH2 and the second hole H2 can be improved by increasing the thickness of the metal film 102. In addition, due to the upper carbon film 103, the diameters of the bottoms of the second memory hole MH2 and the second hole H2 can be increased.

### Fourth Embodiment

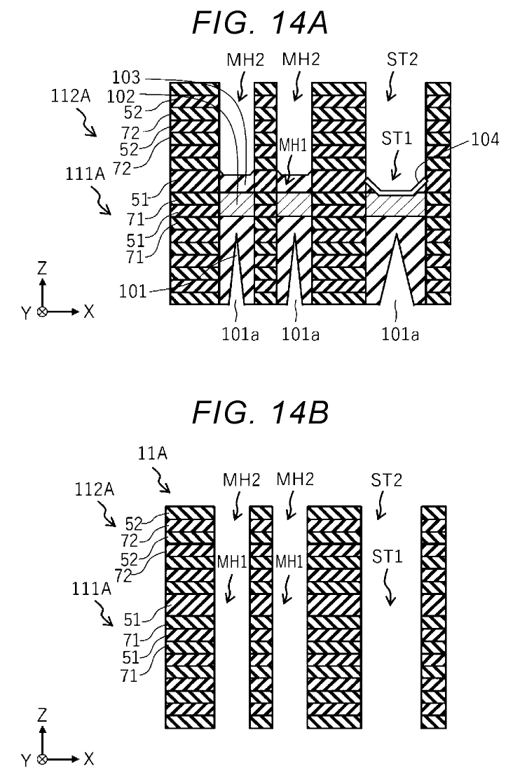

A fourth embodiment in which etching stop layers 101, 102, and 103 are used to form slits ST1 and ST2 that divide the stacked films 111 and 112 in the Y direction will be described, focusing on the differences from the above-mentioned embodiments. FIGS. 14A and 14B are cross-sectional diagrams showing process steps of a manufacturing method of a semiconductor device according to the fourth embodiment.

As shown in FIGS. 14A and 14B, in the fourth embodiment, when forming a first memory hole MH1 that penetrates the lower stacked films 111A, a first slit ST1 that divides the lower stacked films 111A in the Y direction is formed. In FIGS. 14A and 14B, the first slit ST1 extends in the X direction.

After forming the first slit ST1, a lower carbon film 101 is formed in the first slit ST. The formation of the lower carbon film 101 in the first slit ST is performed in the same step (that is, simultaneously) as the formation of the lower carbon film 101 in the first memory hole MH1. The lower carbon film 101 in the first slit ST is processed by etching back to have approximately the same height as the lower carbon film 101 in the first memory hole MH1.

After forming the lower carbon film 101 in the first slit ST1, a metal film 102 is formed on the lower carbon film 101 in the first slit ST1 up to near the upper end of the first slit ST1. The formation of the metal film 102 in the first slit ST1 is performed in the same step as the formation of the metal film 102 in the first memory hole MH1. The metal film 102 in the first slit ST is processed by etching back to have approximately the same height as the metal film 102 in the first memory hole MH1.

After forming the metal film 102 in the first slit ST1, an upper carbon film 103 is formed from the upper surface of the metal film 102 in the first slit ST1 to the upper end of the first slit ST1. The formation of the upper carbon film 103 in the first slit ST1 is performed in the same step as the formation of the upper carbon film 103 in the first memory hole MH1.

After forming the upper carbon film 103 in the first slit ST1, upper stacked films 112A are formed on the lower stacked films 111A and the upper carbon film 103.

After forming the upper stacked films 112A, a second slit ST2 is formed on the first slit ST1, dividing the upper stacked films 112A in the Y direction to reach the upper carbon film 103 or metal film 102 (FIG. 14A). The formation of the second slit ST2 is performed in the same step as the formation of the second memory hole MH2.

After forming the second slit ST2, the lower carbon film 101, the metal film 102, and the upper carbon film 103 are removed to communicate the first slit ST1 with the second slit ST2. An insulating layer, for example, may be formed in the communicated first slit ST1 and second slit ST2.

Therefore, according to the fourth embodiment, it is possible to achieve both an increase in the width of the bottom of the second slit ST2 on the etching stop layer and a selectivity of etching using the etching stop layer.

While certain embodiments have been described, these embodiments have been presented by way of example only, and are not intended to limit the scope of the disclosure. Indeed, the novel embodiments described herein may be embodied in a variety of other forms; furthermore, various omissions, substitutions, and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A manufacturing method of a semiconductor device, comprising:
forming a first stack of films including a plurality of first insulating films and a plurality of first sacrifice films alternately stacked in a first direction;
forming at least one first hole penetrating the first stack of films in the first direction;
forming a metal film in the first hole near an upper end of the first hole;
forming a carbon film on an upper surface of the metal film in the first hole to reach the upper end of the first hole;
forming a second stack of films including a plurality of second insulating films and a plurality of second sacrifice films alternately stacked in the first direction, on the first stack of films;
forming, above the first hole, at least one second hole penetrating the second stack of films in the first direction to reach the carbon film or the metal film; and
removing the carbon film and the metal film to communicate the first hole with the second hole.

2. The manufacturing method according to claim 1, further comprising:
forming a columnar portion in the first hole and the second hole, after removing the carbon film and the metal film.

3. The manufacturing method according to claim 2, wherein the columnar portion includes a lamination of films including a charge storage film and a channel semiconductor film.

4. The manufacturing method according to claim 1, further comprising:
forming a second carbon film in the first hole, before forming the metal film, wherein
the metal film is formed on the second carbon film.

5. The manufacturing method according to claim 4, wherein the second carbon film is formed such that a cavity is formed in a lower surface of the second carbon film.

6. The manufacturing method according to claim 1, wherein
said forming at least one first hole comprises forming a plurality of the first holes, such that a first one of the plurality of first holes has a larger diameter than a second one of the plurality of first holes, and
said forming at least one second hole comprises forming a plurality of the second holes, such that a first one of the plurality of second holes corresponding to the first one of the plurality of first holes has a larger diameter than a second one of the plurality of second holes.

7. The manufacturing method according to claim 6, further comprising:
after removing the carbon film and the metal film, forming a columnar portion in the second one of the first holes, and in the second one of the second holes; and
forming an insulating layer in the first one of the first holes and the first one of the second holes.

8. The manufacturing method according to claim 1, wherein
the metal film is formed such that the metal film has a recess portion, and
the carbon film is formed to fill the recess portion in the metal film.

9. The manufacturing method according to claim 1, further comprising:
forming a concave mark portion used for aligning a mask for photolithography, on the first stack of films away from a position where the first hole is formed in a second direction along an upper surface of the first stack of films, before the first hole is formed, wherein
the first hole is formed by photolithography using the mask aligned using the mark portion.

10. The manufacturing method according to claim 9, wherein
the metal film is further formed on a sidewall of the mark portion, and
the carbon film is further formed on the metal film on the sidewall of the mark portion.

11. The manufacturing method according to claim 1, further comprising:
forming a first slit that divides the first stack of films in a second direction along an upper surface of the first stack of films;
forming the metal film near the upper end of the first slit when the metal film is formed near the upper end of the first hole;
forming the carbon film on the upper surface of the metal film in the first slit to reach the upper end of the first slit when the carbon film is formed;
forming, above the first slit, a second slit that divides the second stack of films in the second direction and reaches the carbon film or the metal film in the first slit; and
removing the carbon film and the metal film in the first slit to communicate the first slit with the second slit.

12. The manufacturing method according to claim 1, wherein the metal film contains at least one of tungsten, titanium nitride, and molybdenum.

13. The manufacturing method according to claim 1, wherein the metal film is formed such that a cavity is formed in a lower surface of the metal film.

14. The manufacturing method according to claim 1, wherein the metal film is formed to be in contact with a lower end of the first hole.

15. A semiconductor device comprising:
a first stack of films including a plurality of first insulating films and a plurality of first electrode films alternately stacked in a first direction, the first stack of films having a concave portion on an upper surface thereof;
a first columnar portion penetrating the first stack of films in the first direction;
a second stack of films provided on the first stack of films and including a plurality of second insulating films and a plurality of second electrode films alternately stacked in the first direction, the second stack of films having a convex portion on a lower surface thereof, the convex portion being formed in the concave portion;
a second columnar portion continuously provided on the first columnar portion and penetrating the second stack of films in the first direction;
a metal film formed between the concave portion and the convex portion in a second direction along the upper surface of the first stack of films; and
a carbon film formed between the concave portion and the convex portion adjacent to the metal film in the second direction.

16. The semiconductor device according to claim 15, wherein the carbon film is formed on an inner surface of the metal film.

17. The semiconductor device according to claim 15, further comprising:
a second carbon film formed on a surface of the concave portion, wherein the metal film is formed between the second carbon film and the carbon film in the second direction.

18. The semiconductor device according to claim 15, wherein
the metal film is formed on an inner surface of the second carbon film, and
the carbon film is formed on an inner surface of the metal film.

19. The semiconductor device according to claim 15, wherein the convex portion is formed on an inner surface of the carbon film.

20. The semiconductor device according to claim 15, wherein the metal film contains at least one of tungsten, titanium nitride, and molybdenum.
